(19) United States
(12) Patent Application Publication
(10) Pub. No.: US 2009/0224949 A1
(43) Pub. Date: Sep. 10, 2009

(54) KEY INPUT APPARATUS

(75) Inventor: Dae-Jin KWON, Uiwang-si (KR)

Correspondence Address: H.C. PARK & ASSOCIATES, PLC, 8500 LEESBURG PIKE, SUITE 7500, VIENNA, VA, 22182, US

(73) Assignee: Pantech&Curitel Communications, Inc., Seoul (KR)

(21) Appl. No.: 12/388,914

(22) Filed: Feb. 19, 2009

(30) Foreign Application Priority Data
Mar. 4, 2008 (KR) 10-2008-0020145

(51) Int. Cl. H03K 17/94

(52) U.S. Cl. 341/22

(57) ABSTRACT

A key input apparatus includes a block unit to block a key recognition signal input through a signal input path from being provided to an end of a switch connected to a signal output path if the switch is in an ON state. Thus, if there multiple key inputs are entered simultaneously or sequentially, a correct key input can be more accurately recognized.

### CROSS REFERENCE TO RELATED APPLICATION

This application claims priority from and the benefit of Korean Patent Application No. 10-2008-0020145, filed on Mar. 4, 2008, which is hereby incorporated by reference for all purposes as if fully set forth herein.

### BACKGROUND OF THE INVENTION

1. Field of the Invention

The present invention relates to a key input apparatus, and more particularly, to a key input apparatus in a mobile communication terminal to reduce the risk of faulty key input sensing.

2. Discussion of the Background

With the development of mobile communication technologies, a mobile communication terminal provides an increasing variety of functions. The mobile communication terminal offers not only voice calls but also quadruple play services including high-speed interactive games, mass data transfer (based on, for example, file transfer protocol (FTP)), and mobile IP-TV services. Accordingly, techniques have been developed to more efficiently provide various multimedia services using the mobile communication terminal.

For example, a user may access a mobile communication network with a mobile communication terminal employing a binary runtime environment for wireless (BREW), which is the next-generation wireless Internet platform. Also, a user can download desired data or, in some circumstances, upgrade mobile communication terminal software wirelessly over a wireless mobile communication network employing BREW. For the mobile communication terminal, the wireless Internet platform of BREW functions as an operating system, and may be middle ware that permits execution of various software including games, videos, and the like. The wireless BREW platform may have advanced three dimensional graphics and high compatibility with the existing systems.

With this increase of services, however, more precise control of the mobile communication terminal may permit further exploitation of the services. For example, to provide a more realistic game environment, it may be helpful to generate a variety of input signals, such as by pressing more than one key on the mobile communication terminal at a time.

However, in the conventional mobile communication terminal key input system, accurate recognition of input keys may be difficult if a key signal is input while other keys are already being pressed, or if three key inputs are generated at the same time.

FIG. 1 is a circuit diagram showing conventional key input recognition signal flow. The difficulty in recognizing accurate key inputs in a conventional key input apparatus will now be discussed with reference to FIG. 1.

If the UP and DOWN keys are input by a user, that is, if second switch SW2 and third switch SW3 are in an ON state, a key detection unit connected to paths (a) and (b) can recognize UP and DOWN key inputs when low signals, referred to as key recognition signals, are provided to second switch SW2 and third switch SW3.

However, if a number 8 key is also pressed, that is, if a switch SW18 is in an ON state while the switch SW3 is in an ON state, the key detection unit may wrongly determine whether switch SW3 is in an ON state.

Similarly, if switch SW17 is in an OFF state but switch SW2 is in an ON state, a key recognition signal detected at path (b) may wrongly indicate that the switch SW17 is in an ON state, and accordingly, a number 7 key, for which switch SW17 is in an OFF state, may be considered by the key detection unit as being pressed.

### SUMMARY OF THE INVENTION

This invention provides a key input apparatus that more accurately recognizes multiple key inputs.

Additional features of the invention will be set forth in the description which follows, and in part will be apparent from the description, or may be learned by practice of the invention.

The present invention discloses a key input apparatus including a first signal input path, a first signal output path, a first switch having a first end connected to the first signal input path and a second end connected to the first signal output path, the first switch to be turned on or off according to a key input, and a block unit to block a key recognition signal at the first signal input path from being provided to the second end of the first switch if the first switch is in an ON state.

The present invention also discloses a key input apparatus including a plurality of signal input paths extending in a first direction, a plurality of signal output paths extending in a second direction to cross with the plurality of signal input paths, a plurality of switches to be turned on or off according to a respective key input, each switch arranged at a crossing region of a signal input path and a signal output path, and each switch including a first end connected to one of the signal input paths and a second end connected to one of the signal output paths, and a block unit connected to a first switch to block a key recognition signal at a first signal input path from being provided to the second end of the first switch if the first switch is in an ON state.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a circuit diagram showing a conventional key input recognition signal flow.

FIG. 2 is a block diagram of a key input apparatus according to an exemplary embodiment of the present invention.

FIG. 3 is a table showing signals to be output by the signal output unit in FIG. 2.

FIG. 4 is a circuit diagram showing key recognition signal flows in a key input apparatus according to an exemplary embodiment of the present invention.

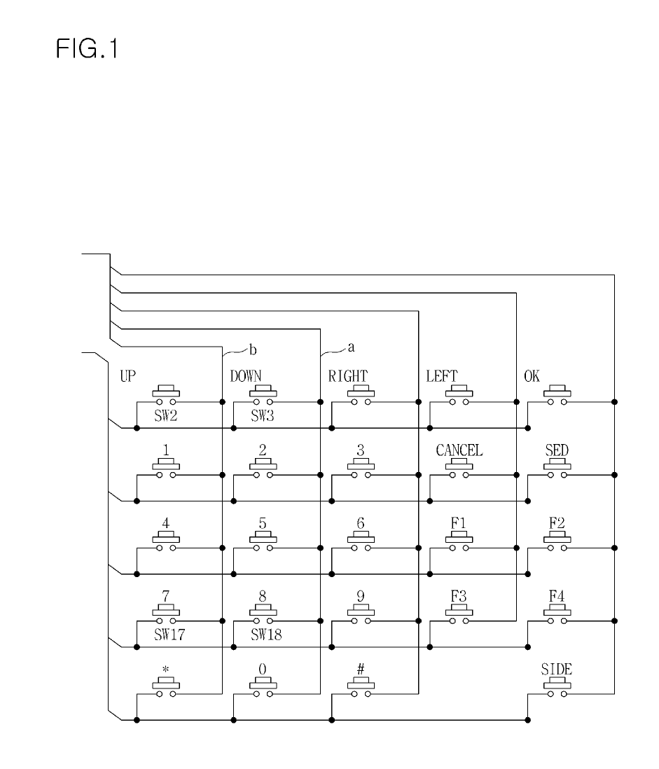

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of elements may be exaggerated for clarity. Like reference numerals in the drawings denote like elements.

It will be understood that when an element is referred to as being “on” or “connected to” another element, it can be directly on or directly connected to the other element, or intervening elements may be present. In contrast, if an element is referred to as being “directly on” or “directly connected to” another element, there are no intervening elements present.

According to the following exemplary embodiment, a key input apparatus may reduce the risk of the incorrect detection of a key input.

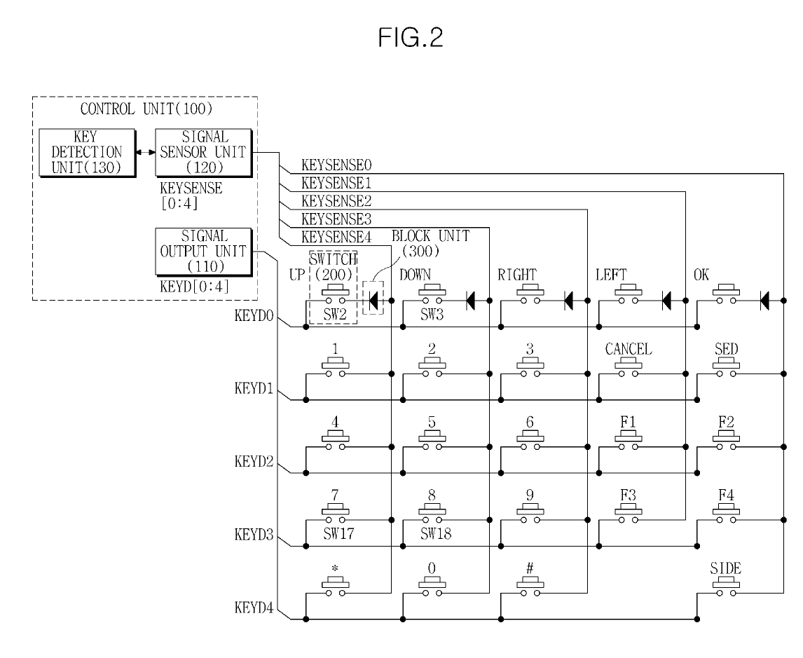

FIG. 2 is a block diagram of a key input apparatus according to an exemplary embodiment. As shown in FIG. 2, the key input apparatus includes a control unit 100, switches 200, and block units 300. Switches 200 may correspond to keys, for example, on a QWERTY-style keyboard of a mobile communication terminal, or on an alpha-numeric style keyboard of a mobile communication terminal.

The control unit 100 may be implemented as a microprocessor included in the mobile communication terminal having the key input apparatus, and the control unit 100 may control the operation of the terminal. As shown, the control unit 100 includes a signal output unit 110 including signal output paths KEYD0, KEYD1, KEYD2, KEYD3, and KEYD4, a signal sensor unit 120 including signal input paths KEYSENSE0, KEYSENSE1, KEYSENSE2, KEYSENSE3, and KEYSENSE4, and a key detection unit 130, which detects a key input based on information of the signal output path and signal input path of a key recognition signal that is input to the signal sensor unit 120.

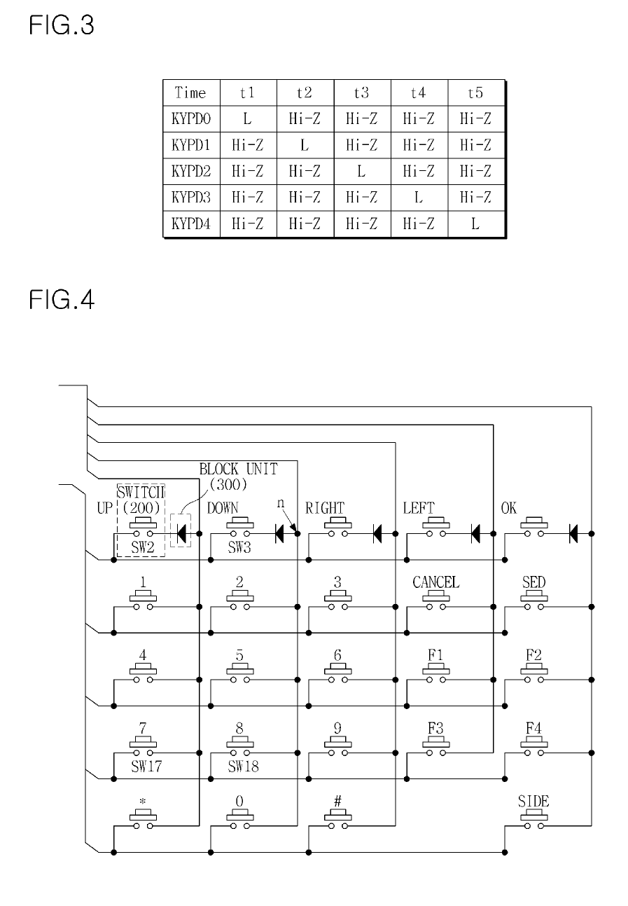

FIG. 3 is a table showing signals to be output by the signal output unit 110 of the key input apparatus of FIG. 2. As shown in FIG. 3, the signal output unit 110 sequentially outputs a low signal (L), which represents a key recognition signal, through one of signal output paths KEYD0, KEYD1, KEYD2, KEYD3, and KEYD4, and outputs high-impedance values Hi-Z through the rest of the signal output paths while the one signal output path has a low signal L.

The key detection unit 130 detects a key input based on information of the signal output path and the signal input path by a key recognition signal input to the signal sensor unit 120. As described above, since the signal output unit 110 outputs a low signal L sequentially through the signal output paths KEYD0, KEYD1, KEYD2, KEYD3, and KEYD4, the key detection unit 130 can identify on which signal output path a key recognition signal is output based on an input-timing difference between the sequentially output key recognition signals.

For example, the key detection unit 130 can determine that a switch SW5, corresponding to a LEFT key input, is in an ON state if a key recognition signal is input to the signal input path KEYSENSE1 at a moment when a low signal L is output through the signal output path KEYD0. In this way, a LEFT key input can be detected. Furthermore, if a key recognition signal input to signal input path KEYSENSE3 is sensed at a moment when the low signal L is output through signal output path KEYD0, the key detection unit 130 can also determine that a switch SW3 is in ON state, and a DOWN key input can be detected.

A block unit 300 has a first end connected to the signal sensor unit 120, and a second end connected to an end of the switch 200. The block unit 300 may block a key recognition signal from passing from the end of the switch 200 connected to the signal output unit 110 to the other end of the switch 200.

More specifically, the block unit 300 may be a diode having an anode connected to the signal sensor unit 120 and a cathode connected to an end of the switch 200 to permit a current to travel from the anode to the cathode. However, the block unit 300 is not limited to the diode. As described above, one end of the switch 200 is connected to the signal output unit 110 through a signal output path, and the other end is connected to the signal sensor unit 120 through a signal input path. Thus, any structure that can block a key recognition signal from flowing from a signal input path to an end of the switch 200 connected to the signal output unit 110 can serve as the block unit 300.

Although the key input apparatus illustrated in FIG. 2 shows block units 300 for only some of the switches 200, the block unit 300 may be provided for each switch 200 of the key input apparatus, and thus the number of block units 300 is not limited.

Furthermore, in the exemplary embodiment, the signal sensor unit 120 may recognize any voltage lower than a potential barrier, or turn-on voltage, of a diode included in block unit 300 as a low signal L. Voltages greater than 0.7 V may be provided to the signal output paths, except for the signal output path through which a low signal L from the signal output unit 110 passes.

FIG. 4 is a circuit diagram for showing key recognition signal flows in a key input apparatus according to an exemplary embodiment.

If there are UP and DOWN key inputs, that is, if switches SW2 and SW3 are in an ON state when the low signal L is output through signal output path KEYD0, the key detection unit 130 recognizes UP and DOWN key inputs when sensing key recognition signals at signal input paths KEYSENSE3 and KEYSENSE4. That is, since the signal output unit 110 outputs a low signal L as a key recognition signal, the key detection unit 130 can determine the UP and DOWN key inputs when the signal input paths KEYSENSE3 and KEYSENSE4 are short-circuited with signal output path KEYD0.

In another example, if a number 8 key is pressed, that is, a switch SW18 is in ON state, a low signal L at KEYSENSE3 would be detected if a low signal L is output to signal output path KEYD3.

If the switch SW3 is also in ON state while switch SW18 is in ON state and a low signal L is output to signal output path KEYD3, a key recognition signal may be applied from a node n toward the switch SW3. However, as described above, when a low signal L is output to signal output path KEYD3, the rest of signal output paths KEYD0, KEYD1, KEYD2, and KEYD4 have high impedances. Therefore, the block unit 300 can block the low signal L from being transferred to the switch SW3. In other words, when a switch SW18 enters an ON state, a key recognition signal output from signal output path KEYD3 and transferred to the node n is only transferred to KEYSENSE3, and not to switch SW3, and key detection unit 130 can more accurately detect that the number key ‘8’ is pressed according to the timing of when the low signal L is provided to signal output path KEYD3.

As described above, according to the exemplary embodiments, it is possible to reduce or prevent faulty key input sensing. Accordingly, a greater variety of key input signals can be generated.

According to the exemplary embodiments, if there are multiple key inputs entered sequentially or simultaneously, each key input can be recognized more accurately. Therefore, it is possible to generate a greater variety of key combinations than with the conventional key input apparatus.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A key input apparatus, comprising:
a first signal input path;
a first signal output path;
a first switch comprising a first end connected to the first signal input path and a second end connected to the first signal output path, the first switch to be turned on or off according to a key input; and
a block unit to block a key recognition signal at the first signal input path from being provided to the second end of the first switch if the first switch is in an ON state.

2. The key input apparatus of claim 1, wherein the block unit is a diode.

3. The key input apparatus of claim 1, further comprising a control unit, the control unit comprising:
a signal output unit connected to the first signal output path, the signal output unit to provide the key recognition signal to the first signal output path;
a signal sensor unit connected to the first signal input path, the signal sensor unit to sense the key recognition signal at the first signal input path if the first switch is in an ON state; and
a key detection unit to detect the key input of the first switch, wherein the block unit has a first end connected to the signal sensor unit and a second end connected to the switch to block the key recognition signal.

4. The key input apparatus of claim 3, wherein the signal output unit sequentially outputs the key recognition signal to the first signal output path and a second signal output path, and the key detection unit identifies the key input of the first switch based on an input-timing difference between the key recognition signal being output to the first signal output path and the second signal output path.

5. The key input apparatus of claim 3, further comprising:
a second switch having a first end connected to the first signal input path and a second end connected to a second signal output path,
wherein the signal output unit sequentially outputs the key recognition signal to the first signal output path and the second signal output path, and the key detection unit identifies a key input of the second switch based on an input-timing difference between the key recognition signal being output to the first signal output path and the second signal output path.

6. The key input apparatus of claim 3, further comprising:
a second switch having a first end connected to a second signal input path and a second end connected to the first signal output path; and
a second signal output path,
wherein the signal output unit sequentially outputs the key recognition signal to the first signal output path and the second signal output path, and the key detection unit identifies a simultaneous key input of the first switch and the second switch based on an input-timing difference between the key recognition signal being output to the first signal output path and the second signal output path.

7. The key input apparatus of claim 1, wherein the block unit is a diode, the key recognition signal has a level lower than a turn-on voltage of the diode, and the first signal output path has a high impedence level when the key recognition signal is not applied to the first signal output path.

8. The key input apparatus of claim 1, wherein the first switch corresponds to a key on an alpha-numeric keypad of a mobile communication terminal.

9. The key input apparatus of claim 1, wherein the first switch corresponds to a key on a QWERTY-style keyboard of a mobile communication terminal.

10. A key input apparatus, comprising:
a plurality of signal input paths extending in a first direction;
a plurality of signal output paths extending in a second direction to cross with the plurality of signal input paths;
a plurality of switches to be turned on or off according to a respective key input, each switch arranged at a crossing region of a signal input path and a signal output path, and each switch comprising a first end connected to one of the signal input paths and a second end connected to one of the signal output paths; and
a block unit connected to a first switch to block a key recognition signal at a first signal input path from being provided to the second end of the first switch if the first switch is in an ON state.

11. The key input apparatus of claim 10, wherein the block unit is a diode.

12. The key input apparatus of claim 10, further comprising a control unit, the control unit comprising:
a signal output unit to sequentially output the key recognition signal through the signal output paths;
a signal sensor unit connected to the signal input paths, the signal sensor unit to sense the key recognition signal at one or more of the signal input paths; and
a key detection unit to detect respective key inputs of the switches,
wherein the block unit has a first end connected to the signal sensor unit and a second end connected to the first switch to block the key recognition signal.

13. The key input apparatus of claim 10, wherein the plurality of switches correspond to keys on an alpha-numeric keypad of a mobile communication terminal.

14. The key input apparatus of claim 10, wherein the plurality of switches correspond to keys on a QWERTY-style keyboard of a mobile communication terminal.
